(19) United States
(12) Patent Application Publication
(10) Pub. No.: US 2022/0372646 A1
(43) Pub. Date: Nov. 24, 2022

(54) METHOD AND DEVICE FOR SYNTHESIS OF DIAMOND AND ALL OTHER ALLOTROPIC FORMS OF CARBON BY LIQUID PHASE SYNTHESIS

(71) Applicant: DIAROTECH SA, Fleurus (BE)

(72) Inventors: Horacio J. TELLEZ OLIVA, Charleroi (BE); Etienne BALTHASART, Thimister-Clermont (BE)

(73) Assignee: DIAROTECH SA, Fleurus (BE)

(21) Appl. No.: 17/641,660

(22) PCT Filed: Sep. 9, 2020
(86) PCT No.: PCT/EP2020/075166

§ 371 Date: Mar. 9, 2022

(30) Foreign Application Priority Data
Sep. 11, 2019 (BE) BE2019/5605

(51) Int. Cl. C25D 13/02; C25D 13/24; C25D 13/18

(52) U.S. Cl. CPC C25D 13/02; C25D 13/24; C25D 13/18

(57) ABSTRACT

The invention relates to the field of liquid phase synthesis of diamond or any other allotropic forms of carbon and more particularly to a process of liquid phase synthesis of carbonaceous films, according to which a voltage is applied, in a solution containing carbonaceous molecules, to a substrate on which a carbonaceous layer is to be deposited and photons are sent to the surface of the substrate. To this end, the invention also relates to a device for the liquid phase synthesis of carbonaceous films comprising a synthesis vessel inside which are arranged means for applying a voltage in a reaction zone, and photonic means are arranged to send photons to the reaction zone.

The invention relates to the field of liquid phase synthesis of diamond or all other allotropic forms of carbon.

Carbon is a material that has several allotropic forms, like e.g., forms of amorphous carbon and forms of crystalline carbon, the best known being fullerene, graphene, graphite, diamond, lonsdaleite, etc. Diamond consists mainly of sp³ hybridised carbon atoms while graphite consists mainly of sp² hybridised carbon atoms. Other “allotropic” forms exist, in the synthetic state, more or less hydrogenated, like DLC (Diamond Like Carbon).

Diamond is a material that has a unique combination of properties like hardness, thermal conductivity or electrical resistivity, which are remarkably interesting for numerous technical applications. The rarity and price of natural diamonds make it impossible to use them on a large scale, thereby limiting their use to luxury jewellery. However, over the past decades, methods of diamond synthesis have been developed in the hope of facilitating access to this material on a larger scale for technical applications.

DLC or Diamond Like Carbon is also an interesting material, differing from diamond by a proportion of sp² hybridised carbon, up to 60%, in sp³ hybridised carbon.

The preferred method for the synthesis of diamond or DLC thin films on a substrate is low-pressure chemical vapour deposition (CVD). According to this method, the diamond is deposited in crystalline form on a substrate placed in a chamber in which a gas carrying carbon atoms is introduced and is then transformed into plasma by an energy source. Several technologies can be used for the formation of plasma, e.g., direct current, electric arc, hot filament, microwaves, or torch, among others. Presently, the apparatus that dominates the market uses microwaves or a hot filament.

In an effort to make the diamond material more technically and economically accessible for numerous technical applications, the applicant has also developed several improved methods of synthesising diamond disclosed, for example, in WO2012013824 or WO2017121892. However, diamonds that are produced synthetically in thin films by CVD remain expensive and thus have limited applications at the moment.

Attempts to synthesise diamond on a silicon substrate by liquid phase ethanol electrolysis have been described by Yoshikatsu Namba as early as 1992, in Journal of Vacuum Science and Technology A: Vacuum, surfaces and Films, 10(5), pp. 3368-3370, and more recently by Ismail et al in Optik (2019), 179, pp. 29-36. These attempts explored the electrolysis of different organic molecules on different substrates and failed to form a consistent crystalline diamond film.

Therefore, the applicant deemed it necessary to improve the formation of diamond in liquid phase, or even to be able to select the allotropic form of the diamond or another form of carbon produced.

To this end, the invention relates firstly to a process for liquid phase synthesis of carbonaceous films, according to which:
a voltage is applied, in a solution containing carbonaceous molecules, to a substrate on which a carbonaceous film is to be deposited, and
photons are sent on the surface of the substrate.

The voltage is applied between at least two electrodes. One of the two electrodes can advantageously comprise or be formed by the substrate.

Here, a voltage means electrical voltage. The electrical voltage is related to the electric current by connections that are well known to the person skilled in the art, depending on the application environment. Here, these two terms are used indifferently to indicate the movement of charge, i.e., of an electrolyte, here ions or charged chemical species inside a conductive medium, here the solution that forms the medium between the electrodes.

While prior art methods of diamond or DLC synthesis allow the formation of very thin films, generally covered with a black-grey deposit typical of graphite formation, the applicant has discovered that the combination of the liquid phase synthesis with photonics, i.e., the application of a light source bringing photons into the synthesis area, allows obtaining a diamond deposit with a clear appearance and characterized by an absorption peak in Raman spectroscopy that is very narrow, which is characteristic of a pure diamond. In particular, photons of suitable or specific wavelength can be sent by irradiation in the ultraviolet (UV) spectrum in order to improve the proportion of the formed sp³ hybridised carbon atoms, and/or in the infrared (IR) spectrum, to guide the reaction in the desired direction, which can act as a catalyst to promote and accelerate the formation of the diamond. In short, one or more wavelengths can be selected to be sent to the substrate, in the entire electromagnetic spectrum, depending on the reagents present, the desired reaction paths and the product to be obtained.

Here, a carbonaceous film refers to a film comprising carbon atoms and preferably sp³ hybridized carbon atoms and preferably diamond. The concept of film is not limiting to a thickness, which can for example range between one nanometre and several millimetres.

Here, and in the following description, diamond refers to all the allotropic forms containing carbon in the sp³ hybridized state, such as diamond, in all its crystalline forms or DLC, as well as doped forms of diamond, like for example with boron or nitrogen.

The substrate can be any substrate on which a carbon layer is to be applied, like for example a rigid layer of silicon, glass, or any other substrate based on molybdenum, iron, nickel, cobalt, tungsten, titanium and/or others.

In particular, the substrate can act as an electrode.

The solution preferably refers to a liquid solution, comprising carbonaceous species. For example, it can be a solvent or a mixture of organic solvents like methanol, ethanol, propanol or isopropanol, or any other substances, preferably but not necessarily liquid, which can provide carbon atoms for the reaction of diamond synthesis. The solution can also be an aqueous solution. Preferably, the solution is polar, which favours the dissociation reaction between the carbon and the polar group associated to it. The solution can be an organic-aqueous mixture.

However, the solution is not necessarily liquid, at least between the electrodes. It can be viscous, like for example a gel or paste, or even solid. Here, the term solution is to be understood in a very broad sense, as long as it allows the movement of charge between the electrodes.

Preferably, the solution contains other carbonaceous molecules like cycloalkanes, and in particular cycloalkanes of the diamondoid type, like for example adamantane, iceane, diamantane or triamantane. This type of organic substances already contain a large number of sp^{a} C—C bonds and are therefore favourable precursors to the formation of diamond in the sense defined above.

In addition to the carbonaceous species, the solution can contain heteroatoms such as nitrogen (N), boron (B), or any other atomic species allowing to dope the diamond deposit in order to give it special properties, mainly for electrical and electronic applications.

The solution may also contain one or more catalysts, such as metallic, non-metallic or ceramic catalysts, including e.g., sulphur or chromium. The electrolyte can act as a catalyst. The selection of a specific catalyst allows either directing the formation reaction towards a specific form of diamond or DLC or improving the deposition kinetics or even the quality of the diamond deposit. These catalysts can, for example, guide an isomerisation of the reaction intermediates into a structure that is close to the desired carbonaceous film. For example, this catalyst can be aluminium trichloride (TAlCl₃) or cadmium sulphide (CdS).

The addition of catalyst allows obtaining more selective reactions.

Preferably, a direct voltage (DC), which can be pulsed, is applied in the solution between the electrodes. Advantageously, a radio frequency (RF) alternating voltage is also applied between the electrodes. This is particularly interesting when the formed diamond film becomes sufficiently thick for its insulating properties to make the application of the DC voltage ineffective.

The DC/RF ratio can be modulated during the synthesis, particularly according to the thickness of the diamond that is already synthesized, so that the diamond deposition speed remains constant.

Surprisingly, it has also been found that the DC/RF ratio has an impact on the crystalline structure of the formed diamond: single crystal, polycrystal of variable and adjustable size.

To homogenize the distribution of the reactive carbon atoms in the solution close to the substrate, a magnetic field can be applied near the substrate. This is particularly useful for large area substrates, e.g., from a few cm². The reactive atoms, instead of following a direct trajectory between the electrodes, also acquire a loop movement, or helical tendency. The reactive atoms thus travel a longer path and gain more speed, increasing the probability of collisions, which generate sp³ hybridised C—C bonds that are characteristic of diamond, and consequently the synthesis speed. This also allows preventing defects in the formed diamond layer or film.

Advantageously, a gas is bubbled through the solution containing carbonaceous molecules. This gas can, for example, be hydrogen H₂ to saturate the solution and produce an evacuation and ripple effect, in the solution, of the hydrogen generated by the diamond formation reaction. In fact, the formation of sp³ C—C bonds requires the breaking of C—H bond thus creating hydrogen radicals that recombine to form dihydrogen H₂. Alternatively or additionally, the bubbling gas can be a carbonaceous gas, such as methane or acetylene, thus providing an additional carbon source for diamond synthesis. The gas can also be an inert gas such as nitrogen or argon. It is also possible to bubble a gaseous mixture comprising two or more of the aforementioned types of gases.

In some cases, the solution containing carbonaceous molecules can also be stirred, for example by using ultrasound, in order to avoid the local precipitation of the carbonaceous molecules and/or to homogenise the solution. In other cases, it can be interesting to not apply stirring, to have carbonaceous molecules in the form of precipitate or crystals on the surface of the substrate. This allows maintaining a certain proximity between the carbon source and the substrate.

The temperature of the solution containing carbonaceous molecules can also be adapted. Adapting the temperature can mean heating; to allow dissolving a greater quantity of carbonaceous species in the solution, saturating it, or even supersaturating it, cooling or maintaining the temperature constant.

For the implementation of the process, the invention also relates to a liquid phase carbonaceous film synthesis device comprising:
a synthesis vessel in which the means for applying a voltage in a reaction zone are arranged, and
photonic means arranged to send photons to the reaction zone.

The means for applying a voltage are preferably electrodes, preferably two electrodes. Advantageously, an electrode can be a substrate on which the carbonaceous film must be deposited, or a substrate holder on which the substrate can be positioned.

One or more electrodes can be transparent or semi-transparent to the wavelength(s) generated by the photonic means, to allow the irradiation of a substrate placed between the electrodes, through this electrode.

The electrodes are connected to a source of direct current (DC), which may be pulsed (referred to in the rest of this document as the “Direct current source”), and/or to a source of radio frequency (RF) alternating voltage.

The reaction zone is preferably restricted to a zone close to a substrate holder, which can be one of the electrodes, and on which the substrate on which a carbonaceous film is to be deposited can be placed. In this case, the electrodes are preferably placed in a parallel manner at a small or medium distance from each other, and the substrate holder electrode is preferably in a horizontal plane.

In the vessel, it is also possible to provide:
means for generating magnetic fields in the reaction zone;
means for stirring or circulating the solution;
means for controlling the temperature of the solution;
a combination of at least two types of the aforementioned means.

The reaction vessel can be provided with a lid, mainly to avoid the evaporation of the solution or the release of bubbling gases.

The photonic means are arranged outside or inside the synthesis vessel and, depending on their arrangement, the part of the vessel or lid through which the photons penetrate the vessel must be transparent to the wavelength of the sent photons.

The photonic means are all means that are suitable for generating photons, means covering the entire electromagnetic spectrum, in the reaction zone, near and/or in the direction of the substrate, like for example a laser, a UV or visible lamp, or an infrared ray generator.

The invention will be better understood with the help of the following description of the preferred form of embodiment of the invention, with reference to the appended drawing in which:

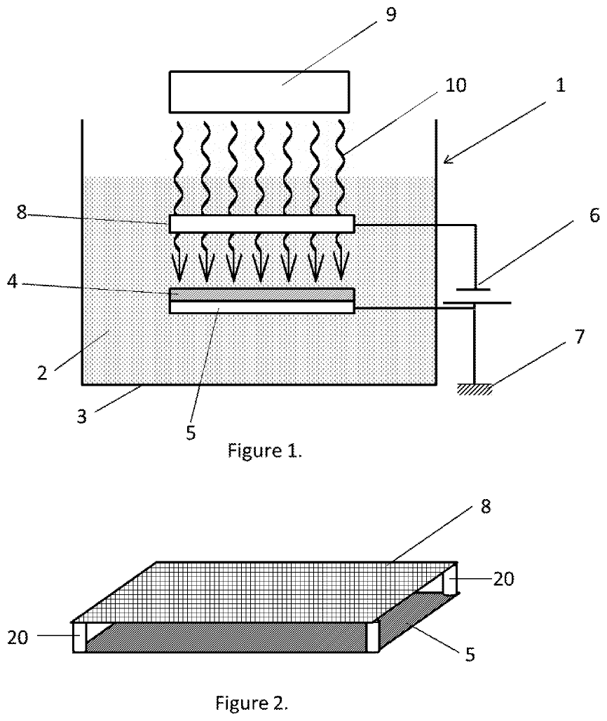

FIG. 1 schematically shows a sectional view of a device for synthesising a carbonaceous film in the liquid phase according to the invention;

FIG. 2 schematically shows a perspective view of the details of FIG. 1;

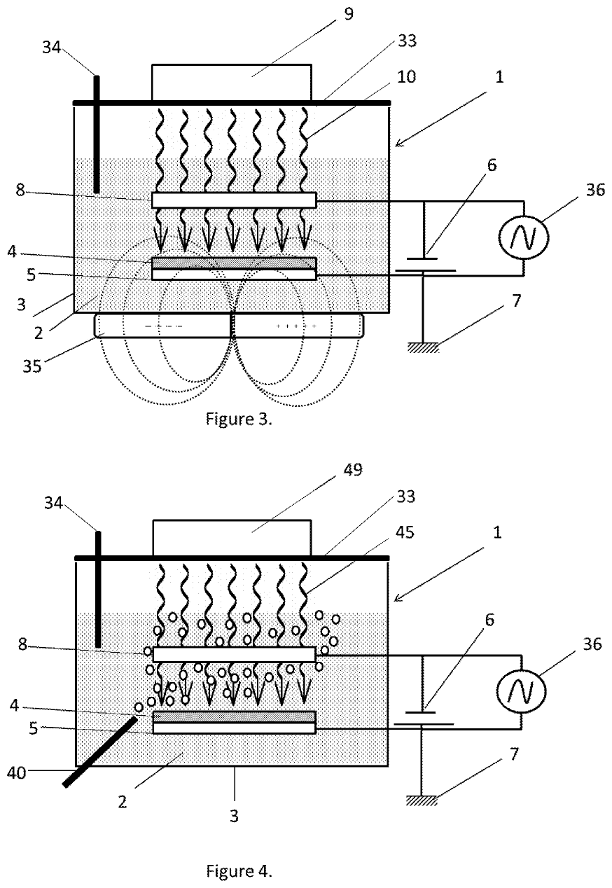

FIG. 3 schematically shows another device for synthesising a carbonaceous film in the liquid phase according to the invention;

FIG. 4 schematically shows yet another device for synthesising a carbonaceous film in the liquid phase according to the invention.

With reference to FIGS. 1 and 2, a device for synthesising a carbonaceous film in the liquid phase 1 comprises a tank 3, inside which two electrodes 5 and 8 are arranged, and are connected to a source of direct current that can be pulsed 6. Electrode 5 is a plate, which, in this case, is arranged horizontally, and also acts as a substrate holder. Substrate 4 on which the diamond is to be synthesised is placed on electrode 5 in this case. Here, electrode 8 is a grate that is placed horizontally above, at a slight distance from electrode 5 (and thus from substrate 4). The distance between the electrodes is ensured, or can even be adjusted during the process, by a suitable device, which in this case entails four Teflon pillars 20 at the four corners of the two electrodes. Vessel 3 is filled with a solution 2 comprising carbonaceous molecules, for example, in this case, it is a solution of adamantane in ethanol. A light box 9 is arranged above the vessel, in this case, for example, a UV light source, which emits photons 10 towards substrate 4, the photons 10 passing through the openings of the grate forming electrode 8.

The electrodes 5 and 8 can have various shapes, such as square or rectangular plates or disks, depending on the shape of the substrate. In this case, electrode 8 is a grate, but could be a plate with holes or having a different pattern or even an electrode that is transparent to the wavelengths of the photons of the light sources used, the main thing being that, if a light source is placed above this electrode 8, the light can pass through it.

Here, light source 9 is shown to be placed above vessel 3, but there can be other configurations, for example with a lateral light source reaching the substrate 5 in an oblique manner, or by the use of judiciously placed mirrors.

Device 1 as shown here is ready for use, or even in operation. In fact, vessel 3 is filled with a solution 2 of adamantane in ethanol, and substrate 4 is placed on the substrate holder. This entire unit forms electrode 5 and UV rays are sent to substrate 4. The diamond synthesis starts as soon as a DC voltage is applied.

The electrical energy applied between the electrodes mainly has the effect of dissociating certain bonds, like for example C—H bonds, thus generating reactive species, such as hydrogen and carbon radicals. These carbon radicals can then either rebond with hydrogen radicals or with other carbon radicals, leading to the formation of a C—C bond (sp, sp² or sp³); the hydrogen radicals can also bond with each other to form dihydrogen gas.

The energy required by liquid phase synthesis is much lower than the energy required for diamond synthesis by the traditional CVD technique. In fact, the generation of a plasma is very energy-intensive while the liquid phase synthesis can take place at ambient temperature, and does not require the application of a vacuum. The device is thus simpler to manufacture. There are fewer risks related to high temperatures and lesser complications related to the airtightness of the device to maintain the vacuum. Substrate 4 can also contain species that enable initiating the formation of C—C bonds (sp, sp² or sp³), like for example precursors (carbon atoms) or catalysts (heteroatoms), upon contact with it.

Optionally, a separate mask can be placed on substrate 4 to limit its accessible surface, especially by photons, in order to give specific dimensions or shapes to the deposit, or to avoid deposition on certain zones of substrate 4.

The probability of collisions between reactive carbon atoms is directly proportional to the volume density of these reactive carbon atoms near the substrate, which is itself related to the energy applied between electrodes 8 and 5.

As diamond is an electrical insulator, as the diamond layer deposited on the substrate thickens, it forms a barrier to the direct current passing between electrodes 5 and 8, particularly when the diamond layer attains a few tenths of microns in thickness. As a result, for the same voltage applied, during the growth of the diamond deposit, the amount of current flowing through the reaction medium decreases. This results in a decrease in the volume density of the reactive atoms and a decrease in the speed of diamond deposition.

In order to be able to form layers thicker than a few tenths of microns, the applicant proposes to combine the direct current (DC) source with a radio frequency (RF) current source.

Moreover, the depletion of reactive species over time tends to reduce the deposition speed. The applicant thus proposes using a device allowing to ensure the consistency of the chemical composition of the solution like for example a means for recirculation of the solution or even work in open hydraulic circuit (constant addition of “new” solution and constant elimination of “used” solution).

With reference to FIG. 3, where the numbering of FIG. 1 is reused for identical elements, here, electrodes 5 and 8 are connected to direct current source 6 and the alternating current (RF) source 36. The system can be programmed so that the RF current takes over from the DC voltage from a certain point of time in the synthesis, either based on a period of time, or based on a synthesised diamond thickness, or even based on the deposition speed.

Radio frequency alternating current source 36 preferably has a filter, at its outlet, to prevent the direct current of source 6 from going back into source 36. Direct current source 6 also preferably has a filter, at its outlet, to prevent the radio frequency alternating current of source 36 from flowing back into source 6.

The ratio between the two currents, DC/RF ratio, can be maintained at the same value during the synthesis. Surprisingly, it has been observed that the DC/RF ratio affects the crystalline form of the diamond deposited on the substrate. For example, in a configuration allowing to form diamond ultra-nano-crystals on a substrate with the application of a DC voltage only, the application of current (RF) in a RF/DC power ratio of 0.05 to 0.3 allows obtaining a deposit formed by larger crystals, i.e., from a sub-micrometre size to several tens of microns.

The ratio between the two currents, DC/RF ratio can also be varied during the synthesis to optimise the synthesis speed. For example, the RF current can gradually take over from the direct current as the deposited diamond layer thickens. For example, the DC/RF ratio could also be selected and regulated according to the properties desired for the deposit or to obtain “composite” deposits with different microstructures/compositions at different areas on the substrate or with different thicknesses of the deposit.

The hybrid feed system of the electrodes thus improves the speed of diamond deposition, by compensating for the electrical insulating effect of the diamond that is already deposited. It also allows playing on the characteristics such as the structure and the properties of the deposit.

The device shown in FIG. 3 also includes a magnetic field source 35, which, in this case, is placed under vessel 3 and generates a magnetic field that is represented by the dotted lines, extending till electrode 5. The magnetic field source 35 can, for example, be an electromagnet or a permanent magnet. This magnetic field allows the homogenisation of the reactive substances in the device, and also their acceleration to increase the chances of collisions between reactive carbons. An ultrasonic generator 34 is also immersed in solution 2 for better homogenisation of the solution. Ultrasound also helps preventing the precipitation of organic molecules. A lid 33 is also placed on the vessel, in order to prevent the liquids from projecting out of the vessel as well as the contamination of the solution containing the carbonaceous species by external elements. In this case, the lid 33 must be transparent to the UV emitted by the light box, and is, for example, made of quartz. In general, the lid must be transparent to the wavelength of the light box, when light is to pass through it.

Here, only one magnet is shown under electrode 5, but it could be placed near electrode 8. There could also be several magnets, mainly one near electrode 5 and one near electrode 8.

During the synthesis, the reactive atoms, moving between the electrodes under the effect of the electric field created between electrodes 5 and 8, are also subjected to the magnetic field, in the vicinity of substrate 4. Their trajectory is thus deviated under the action of the Lorentz force, the effect of the electric and magnetic fields adding up on each charged/reactive atom: the charged atoms will then tend to follow a helical trajectory, which is longer than in the presence of a single field, forming loops around the magnetic field lines. The addition of the effects of the two fields will also accelerate the movement of the reactive atoms.

Thus, the reactive atoms traveling faster along a longer trajectory have a higher probability of collision, which results in an increase in the concentration of activated chemical species and ultimately an increase in the speed of formation of the deposit of the carbon film on the substrate.

With reference to FIG. 4, using the numbering of the previous figures for the common elements, electrodes 5 and 8 are connected to a radio frequency (RF) alternating current source 36 and to ground 7, in parallel with the circuit comprising the direct current source 6. Here, the device does not include a magnet, but has a bubbling cannula 40, allowing a gas, or a mixture of gases, to be bubbled into the reactive medium, preferably towards the area between the electrodes, to create a flow of gas allowing to take, for example, the hydrogen formed in the synthesis reaction, or even to provide, if it is a carbonaceous gas, reactive species useful for the synthesis.

The light box 49 is a combined IR and UVC ray source. The UVC promote the dissociation of C—H bonds, while IR promotes molecular agitation and increases the chances of collision. IR can be considered as a heat source.

Alternatively or additionally, a hot plate or any other temperature regulation system could be placed at the level of the vessel to control and adjust the temperature of the solution containing the carbonaceous species.

Similarly, to further improve the effectiveness of the synthesis reaction, and in particular the specificity of this reaction, the principles described in WO2017121892 can be applied. In particular, photons of particular energies, selected, for example, to correspond to an absorption frequency of the material to be synthesised and/or of a reagent, can be sent to the substrate to improve the speed of formation of the material. The technical characteristics of the various embodiments described above can of course be combined with each other.

The method of the invention can advantageously be used as a first step to form a carbonaceous ‘anchor’ layer on a substrate, to then facilitate a conventional deposition by CVD.

The method of the invention can also be used to form a carbonaceous layer, e.g., diamond or DLC, on large surfaces, such as substrates for microelectronics, glass, photovoltaic panels, etc.

For example: In a vessel of 100 to 500 mL (but not limited to these values) an electrode (10×10mm) made of tungsten, or molybdenum or silicon is placed on top, a few tens of millimetres from a substrate (10×10mm) made of tungsten, or molybdenum or silicon. If a magnet is used, a transverse magnetic field of 0.03 to 1 T is produced by an electromagnet. When a hybrid DC/RF power source is used, both sources are applied at the same time for the entire duration of the deposition.

The solution containing carbonaceous molecules consists of a mixture of ethanol and adamantane in proportions ranging from saturation to pure ethanol.

The temperature of the solution in the vessel is maintained between 20° C. and 60° C. The light box has a 60W UVC power source.

The direct current is applied via a direct voltage between 50 and 200V. If a radio frequency voltage is applied, the frequency of 13.56 MHz is used.

Several diamond deposits have been made by applying a direct current or a hybrid DC/RF current, with or without a magnet placed under the substrate, for about ten minutes.

The results are given in the table below:

| | Mixture | Voltage | Nature of | Thickness | Time |
|---|---|---|---|---|---|
| | (in % in EtOH) | (DC + RF) | the deposit | [μm] | [min] |
| 1 | 2% water | 60 V + 0 W | Diamond | 0.1 | 15 |
| | | | and graphite | | |
| 2 | 2% water + 1% adamantane | 40 V + 5 W | Diamond | 0.1 | 15 |
| | | | and DLC | | |
| 3 | 2% water + 1% adamantane + | 40 V + 5 W | Diamond | 0.25 | 10 |
| | 10 ppm AlCl₃ | | | | |
| 4 | 2% water + 1% cyclohexane + | 20 V + 10 W | Diamond | 0.25 | 10 |
| | 1% adamantane + 10 ppm | | | | |
| | AlCl₃ (+FDV) | | | | |
| 5 | 2% water + 1% adamantane + | 20 V + 10 W | Diamond | 0.4 | 10 |
| | 10 ppm CdS (+FDV) | | | | |
| 6 | 2% water + 1% adamantane + | 20 V + 10 W | Diamond | 0.5 | 15 |
| | 10 ppm CdS (+FDV) | | | | |

Remarks:
The mixtures as explained above express the percentages of solutes dissolved in ethanol, the ethanol content of the mixtures always corresponds to “the balance” i.e., 100% minus the sum of the percentages of solutes.

The mention (FDV) means that the median, i.e., the centre between the electrodes, consists of a glass fibre, i.e., a woven mat made of small glass fibres of the same section as the samples and a few mm thick, soaked in the solution and where nanodiamonds were embedded. This fibre plays multiple roles. It facilitates the removal of hydrogen from the medium and supporting a catalyst (here the nanodiamonds).
Each experiment above involved bubbling with hydrogen.
The above results were obtained with a positive molybdenum electrode and a negative electrode or substrate also made of molybdenum, which were spaced 4 to 6 mm apart. Similar results were obtained with a silicon substrate and a tungsten substrate.
The above results were obtained at room temperature.

Comparison of lines 1 and 2 of the above table shows that the presence of adamantane (a diamondoid) helps increasing the proportion of sp³ carbon in the obtained material. The comparison of lines 2 and 3 or 2 and 4 of the above table show the effect of the AlCl₃ catalyst to improve the selectivity of the reaction (pure diamond obtained) and the reaction kinetics (thicker layer in less time). Lines 5 and 6 also prove the effectiveness of other catalysts, such as cadmium sulphide.

The water in the solution helps to improve the conductivity of the medium and provide protons (H+).

1. A process of liquid phase synthesis of carbonaceous films, according to which:
a voltage is applied, in a solution containing carbonaceous molecules, to a substrate on which a carbonaceous film is to be deposited;
photons are sent on the surface of the substrate, and
a carbonaceous film is formed on the substrate by conversion of the carbonaceous molecules under the action of the voltage and photons.

2. The process according to claim 1, according to which the voltage is applied between at least two electrodes.

3. The process according to claim 2 in which one of the electrodes comprises the substrate.

4. The process according to claim 1, in which the solution containing carbonaceous molecules comprises at least one organic or inorganic solvent.

5. The process according to claim 1, in which the solution containing carbonaceous molecules comprises cycloalkanes, and preferably diamondoid cycloalkanes.

6. The process according to claim 1, in which the solution containing carbonaceous molecules comprises at least one catalyst.

7. The process according to claim 1, according to which the substrate is subjected to a direct voltage (DC) and/or a radio frequency (RF) alternating voltage.

8. The process according to claim 1, according to which a magnetic field is applied close to the substrate.

9. The process according to claim 1, according to which a gas is bubbled through the solution containing carbonaceous molecules.

10. The process according to claim 1, according to which the solution containing carbonaceous molecules is stirred and/or circulated.

11. The process according to claim 1, according to which the temperature of the substrate and/or the solution containing carbonaceous molecules is regulated.

12. A device for liquid phase synthesis of carbonaceous films comprising:
a synthesis vessel in which means for applying a voltage in a reaction zone are arranged, and
photonic means arranged to send photons to the reaction zone.

13. The device according to claim 12, in which the means for applying a voltage comprises at least two electrodes.

14. The device according to claim 13, in which the electrodes are connected to a direct voltage source and/or a radio frequency (RF) alternating voltage source.

15. The device according to claim 12, comprising in addition:
means for generating a magnetic field in the reaction zone, and/or
means for stirring and/or circulation, and/or
means for temperature regulation, and/or
means for injecting a gas or a mixture of gases by bubbling, and/or
a lid to close the vessel.

16. The device according to claim 12, in which the photonic means comprise at least one light source emitting at least one wavelength that can be selected from the entire electromagnetic spectrum.
